(19) United States
(12) Patent Application Publication
(10) Pub. No.: US 2025/0108393 A1
(43) Pub. Date: Apr. 3, 2025

(54) LIQUID PROCESSING METHOD, DISCHARGE ADJUSTMENT METHOD, AND LIQUID PROCESSING APPARATUS

(71) Applicant: Tokyo Electron Limited, Tokyo (JP)

(72) Inventors: Hiroshi MARUMOTO, Kumamoto (JP); Kenji FUKUSHIMA, Kumamoto (JP)

(73) Assignee: Tokyo Electron Limited, Tokyo (JP)

(21) Appl. No.: 18/836,386

(22) PCT Filed: Jan. 26, 2023
(86) PCT No.: PCT/JP2023/002482

§ 371 Date: Aug. 7, 2024

(30) Foreign Application Priority Data
Feb. 8, 2022 (JP) 2022-018227

(51) Int. Cl. B05B 11/00; B08B 3/04; B08B 13/00; H01L 21/02

(52) U.S. Cl. CPC B05B 11/0062; B08B 3/04; B08B 13/00; H01L 21/02002

(57) ABSTRACT

A processing liquid is sent to a discharge nozzle through a processing liquid valve to discharge the processing liquid from the discharge nozzle toward a substrate. The processing liquid valve controls a flow of the processing liquid in a flow channel that is connected to the discharge nozzle, depending on a pressure of a working fluid that is supplied thereto. A fluid pressure adjustment unit adjusts behavior of a variation of a pressure of the working fluid that is supplied to the processing liquid valve, depending on an adjustment parameter that is set variably. The processing liquid that is sent to the discharge nozzle through the processing liquid valve is limited to stop discharge of the processing liquid from the discharge nozzle. Correlation data are acquired between a working fluid parameter that indicates behavior of a variation of a pressure of the working fluid and the adjustment parameter.

### FIELD

The present disclosure relates to a liquid processing method, a discharge adjustment method, and a liquid processing apparatus.

### BACKGROUND

It is possible to execute on/off of discharge of a processing liquid from a discharge nozzle to a substrate by opening/closing of a valve that is provided in a flow channel on an upstream side of such a discharge nozzle (see, for example, Patent Literature 1).

For a valve that is capable of switching on/off of discharge of a processing liquid from a discharge nozzle, for example, a pneumatic switching valve is available that opens or closes a flow channel, depending on a pressure of a working fluid (compressed air, etc.) that is supplied thereto.

### CITATION LIST

### Patent Literature

Patent Literature 1: Japanese Patent Application Publication No. 2001-267236

### SUMMARY

Although behavior of a stop of discharge of a processing liquid in a discharge nozzle is adjustable by, for example, adjusting an opening degree of a fluid flow channel where a working fluid flows that is supplied to a pneumatic switching valve as described above, such an opening degree of a flow channel is frequently determined based on an experience of a manager.

When discharge of a processing liquid from a discharge nozzle is stopped, it takes a reasonable time (that will also be referred to as a “discharge stop time” below) after transmission of a discharge stop signal and before discharge of a processing liquid from a discharge nozzle is stopped completely. In such a discharge stop time, abnormality such as dropping of a liquid droplet(s) from a discharge nozzle may occur where a manager may be needed to confirm presence or absence of such abnormality visually.

In a situation where determination of an opening degree of a fluid flow channel and confirmation of behavior of a stop of discharge of a processing liquid are executed manually as described above, labor and quality of actual work are influenced by experience and/or ability of a manager so as to be readily destabilized.

The present disclosure provides an advantageous technique for stably detecting behavior of a stop of discharge of a processing liquid from a discharge nozzle.

An aspect of the present disclosure relates to a liquid processing method, including a step of sending a processing liquid to a discharge nozzle through a processing liquid valve to discharge the processing liquid from the discharge nozzle toward a substrate where the processing liquid valve controls a flow of the processing liquid in a flow channel that is connected to the discharge nozzle, depending on a pressure of a working fluid that is supplied thereto, and a fluid pressure adjustment unit adjusts behavior of a variation of a pressure of the working fluid that is supplied to the processing liquid valve, depending on an adjustment parameter that is capable of being set variably, a step of limiting the processing liquid that is sent to the discharge nozzle through the processing liquid valve to stop discharge of the processing liquid from the discharge nozzle, and a step of acquiring correlation data between a working fluid parameter that indicates behavior of a variation of a pressure of the working fluid that is acquired by a fluid pressure measurement unit that measures a pressure of the working fluid that is supplied to the processing liquid valve, and the adjustment parameter.

According to the present disclosure, it is advantageous in detecting behavior of a stop of discharge of a processing liquid from a discharge nozzle stably.

### BRIEF DESCRIPTION OF DRAWINGS

FIG. 1 is a diagram that illustrates an outline of an example of a processing system.

FIG. 2 is a diagram that illustrates a schematic configuration of an example of a liquid supply system in a processing unit.

FIG. 3 is a diagram for explaining a discharge stop time.

FIG. 4 is a diagram that illustrates an example of a relationship between an opening degree of a fluid flow channel that is adjusted by a fluid pressure adjustment unit and a discharge stop time,

FIG. 5 is a diagram that illustrates an example of a relationship between a time passage and a working fluid pressure that is a result of measurement by a fluid pressure measurement unit, in a case where discharge of a processing liquid from a discharge nozzle is stopped.

FIG. 6 is a graph that illustrates an example of a relationship between an opening degree of a fluid flow channel that is adjusted by a fluid pressure adjustment unit and an attenuation rate, concerning a result as illustrated in FIG. 5.

FIG. 7 is a graph that illustrates an example of a relationship between a fluid flow channel opening degree and an attenuation rate, concerning only results as illustrated by “Q2” to “Q17” among results as illustrated in FIG. 6.

FIG. 8 is a perspective view that illustrates an example of a specific configuration of a processing unit.

FIG. 9 is a diagram that illustrates an example of a relationship between a time passage and an intensity of reflected light that is acquired by a light measurement unit.

FIG. 10 is a diagram that illustrates an example of a relationship between a time passage, and a working fluid pressure and an intensity of reflected light in a case where discharge of a processing liquid from a discharge nozzle is stopped.

FIG. 11 is a diagram that illustrates an example of a relationship between a time passage, and a working fluid pressure and an intensity of reflected light in a case where discharge of a processing liquid from a discharge nozzle is stopped.

FIG. 12 is a diagram that illustrates an example of a relationship between a delay time and a discharge stop time.

FIG. 13 is a diagram that illustrates an example of a relationship between an attenuation rate, and a delay time and a discharge stop time.

FIG. 14 is a diagram that illustrates a process flow of a first application example.

FIG. 15 is a diagram that illustrates a process flow of a second application example.

FIG. 16 is a diagram that illustrates an example of a correlation between an attenuation rate and a delay time.

FIG. 17 is a diagram that illustrates an example of a relationship between an attenuation rate, and a delay time and a discharge stop time.

FIG. 18 is a diagram that illustrates a process flow of a third application example,

FIG. 19 is a diagram that illustrates an example of a relationship between a time passage, and a working fluid pressure and an intensity of reflected light in a case where discharge of a processing liquid from a discharge nozzle is stopped, in particular, a case where unintended dropping of a liquid droplet(s) from such a discharge nozzle is absent.

FIG. 20 is a diagram that illustrates an example of a relationship between a time passage, and a working fluid pressure and an intensity of reflected light in a case where discharge of a processing liquid from a discharge nozzle is stopped, in particular, a case where unintended dropping of a liquid droplet(s) from such a discharge nozzle is present.

FIG. 21 is a diagram that illustrates a process flow of a fifth application example,

FIG. 22 is a diagram that illustrates an example of a relationship between a time passage and an attenuation rate/a delay time, in particular, illustrates a case where a significant difference between temporal variations of such an attenuation rate and such a delay time is absent.

FIG. 23 is a diagram that illustrates an example of a relationship between a time and an attenuation rate/a delay time, in particular, illustrates a case where a significant difference between temporal variations of such an attenuation rate and such a delay time is present.

### DESCRIPTION OF EMBODIMENTS

Hereinafter, an embodiment(s) of the present disclosure will be explained with reference to the drawing(s).

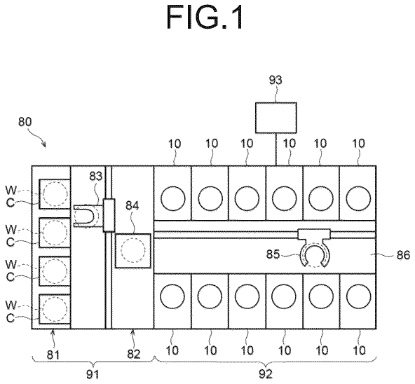

FIG. 1 is a diagram that illustrates an outline of an example of a processing system 80.

The processing system 80 as illustrated in FIG. 1 has a carrying-in/out station 91 and a processing station 92. The carrying-in/out station 91 includes a placing unit 81 that includes a plurality of carriers C, and a transfer unit 82 that is provided with a first transfer mechanism 83 and a delivery unit 84. Each carrier C houses a plurality of substrates W in a horizontal state thereof. A substrate W is typically composed of a semiconductor wafer, a glass substrate, etc., and is not limited thereto. The processing station 92 is provided with a plurality of processing units 10 that are placed at both sides of a transfer path 86, and a second transfer mechanism 85 that moves in a reciprocating manner on the transfer path 86.

A substrate W is taken out of a carrier C by the first transfer mechanism 83, placed on the delivery unit 84, and taken out of the delivery unit 84 by the second transfer mechanism 85. Then, a substrate W is carried in a corresponding processing unit 10 by the second transfer mechanism 85, and a predetermined liquid process is applied thereto in such a corresponding processing unit 10. Subsequently, a substrate W is taken out of a corresponding processing unit 10 by the second transfer mechanism 85, placed on the delivery unit 84, and subsequently, returned to a carrier C of the placing unit 81 by the first transfer mechanism 83.

The processing system 80 includes a controller 93. The controller 93 is composed of, for example, a computer, and includes an arithmetic processing unit and a storage. A program and data for various types of processes that are executed in the processing system 80 are stored in a storage of the controller 93, An arithmetic processing unit of the controller 93 appropriately reads and executes a program that is stored in a storage, so that various types of mechanisms of the processing system 80 are controlled so as to execute various types of processes.

A program and data that are stored in a storage of the controller 93 may be recorded in a computer-readable storage medium and installed from such a storage medium to such a storage. For a computer-readable storage medium, for example, a hard disk (HD), a flexible disk (FD), a compact disk (CD), a magnetooptical disk (MO), and a memory card, etc., are provided.

Two or more of a plurality of processing units 10 in the processing system 80 as described above may have configurations that are identical to one another, may have configurations that are different from one another, may execute processes that are identical to one another, or may execute processes that are different from one another. Each processing unit 10 provides various types of processing liquids (for example, a chemical liquid, a rinse liquid, and a cleaning liquid, etc.) to a substrate W, so that it is possible to apply various liquid processes to such a substrate W.

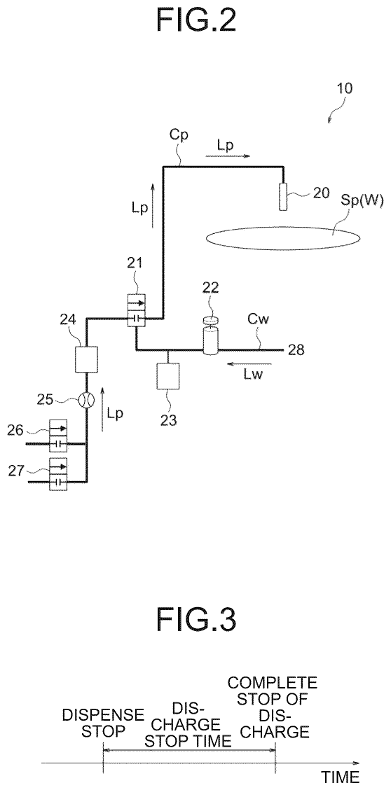

FIG. 2 is a diagram that illustrates a schematic configuration of an example of a liquid supply system in a processing unit 10.

The processing unit (a liquid processing apparatus) 10 includes a discharge nozzle 20 that discharges a processing liquid Lp toward a processing surface Sp (for example, an upper surface of a substrate W) of a substrate W.

A processing liquid flow channel Cp that is connected to a discharge nozzle 20 is provided with a processing liquid valve 21, a constant pressure valve 24, a flowmeter 25, a first supply valve 26, and a second supply valve 27. At a downstream side of the first supply valve 26 and the second supply valve 27, the flowmeter 25, the constant pressure valve 24, the processing liquid valve 21, and the discharge nozzle 20 are provided from an upstream side to a downstream side in this order. For terms of “upstream” and “downstream” herein, a flow of a processing liquid Lp in a processing liquid flow channel Cp at a time when a processing liquid Lp is discharged from the discharge nozzle 20 is a reference thereof.

The first supply valve 26 and the second supply valve 27 are provided in two branched flow channels that are provided in parallel in a processing liquid flow channel Cp, respectively, so as to control a flow of a processing liquid Lp in a corresponding branched flow channel. Each of the first supply valve 26 and the second supply valve 27 is capable of being composed of, for example, an on-off valve, so that it is possible to switch between on (fully open) and off (fully closed) of a flow of a processing liquid Lp in a corresponding branched flow channel under control of a controller 93 (see FIG. 1).

The flowmeter 25 and the constant pressure valve 24 are provided a single flow channel part where two branched flow channels that are provided with the first supply valve 26 and the second supply valve 27 are joined, at a downstream side of the first supply valve 26 and the second supply valve 27. The flowmeter 25 measures a flow rate (that is, a flow velocity) of a processing liquid Lp in a processing liquid flow channel Cp and transmits a result of measurement to the controller 93. Even if a pressure of a processing liquid Lp in a processing liquid flow channel Cp at an upstream side of the constant pressure valve 24 is higher than a set pressure, the constant pressure valve 24 adjusts a pressure of a processing liquid Lp in a processing liquid flow channel Cp at a downstream side thereof so as to be such a set pressure.

The processing liquid valve 21 controls a flow of processing liquid Lp in a processing liquid flow channel Cp, depending on a pressure of a working fluid Lw that is supplied from a fluid supply unit 28 through a fluid flow channel Cw.

That is, an opening degree of processing liquid flow channel Cp that is adjusted by the processing liquid valve 21 varies, depending on a pressure of a working fluid Lw that is supplied to the processing liquid valve 21, and as a result, a flow rate of a processing liquid Lp that is sent from the processing liquid valve 21 to the discharge nozzle 20 is changed. Thus, a processing liquid Lp that is sent to the discharge nozzle 20 through the processing liquid valve 21 is limited, depending on an opening degree of a processing liquid flow channel Cp that is adjusted by the processing liquid valve 21, For example, in a case where an opening degree of a processing liquid flow channel Cp is adjusted so as to be “0 (zero)” by the processing liquid valve 21 (that is, a case where a processing liquid flow channel Cp is fully opened), a processing liquid Lp is not sent from the processing liquid valve 21 to the discharge nozzle 20, so that discharge of such a processing liquid Lp from the discharge nozzle 20 is stopped.
a rate of a variation of an opening degree of a processing liquid flow channel Cp that is adjusted by the processing liquid valve 21 is changed, depending on behavior of a variation of a pressure of a working fluid Lw that is supplied to the processing liquid valve 21. For example, in a case where a variation of a pressure of a working fluid Lw that is supplied to the processing liquid valve 21 is rapid, a rate of a variation of an opening degree of a processing liquid flow channel Cp is also rapid, and as a result, a discharge state of a processing liquid Lp from the discharge nozzle 20 is also changed rapidly. On the other hand, in a case where a variation of a pressure of a working fluid Lw that is supplied to the processing liquid valve 21 is gradual, a rate of a variation of an opening degree of a processing liquid flow channel Cp is also gradual, and as a result, a discharge state of a processing liquid Lp from the discharge nozzle 20 is also changed gradually.

The processing liquid valve 21 in the present embodiment is composed of a pneumatic switching valve (an on-off valve) that utilizes compresses air as a working fluid Lw, and is also referred to as a stop valve or a dispense valve. A pressure of a working fluid Lw that is supplied to the processing liquid valve 21 is changed under control of the controller 93, so that it is possible for the processing liquid valve 21 to switch between on (full open) and off (full closed) of a flow of a processing liquid Lp in a processing liquid flow channel Cp. In particular, the processing liquid valve 21 in the present example adjusts an opening degree of a processing liquid flow channel Cp so as to be decreased, as a pressure of a working fluid Lw that is supplied to the processing liquid valve 21 is decreased.

Additionally, a working fluid Lw is not limited to compressed air and it is possible to use any fluid (a liquid and a gas) as such a working fluid Lw.

Thus, a processing liquid Lp is sent to the discharge nozzle 20 through the processing liquid valve 21 so as to be discharged from the discharge nozzle 20 toward a processing surface Sp of a substrate W.

A fluid flow channel Cw is provided with a fluid pressure adjustment unit 22 and a fluid pressure measurement unit 23.

The fluid pressure adjustment unit 22 adjusts behavior of a variation of a pressure of a working fluid Lw that is supplied to the processing liquid valve 21, depending on an adjustment parameter that is capable of being set variably. Specifically, it is possible for the fluid pressure adjustment unit 22 to adopt an opening degree of a fluid flow channel Cw (for example, an opening degree of an opening/closing tool that changes a cross section of a fluid flow channel Cw) as such an adjustment parameter.

Changing of an adjustment parameter for the fluid pressure adjustment unit 22 may be manually executed by a manager or may be mechanically executed under control of the controller 93. For example, in a case where the fluid pressure adjustment unit 22 is composed of a needle valve, rotation (for example, a rotational frequency and/or an angle of rotation) of an opening degree adjustment screw of such a needle valve is adjusted manually or by a dedicated electrical device (where illustration thereof is omitted), so that it is possible to adjust an opening degree of a fluid flow channel Cw.

Thus, the fluid pressure adjustment unit 22 that adjusts behavior of a variation of a pressure of a working fluid Lw that is supplied to the processing liquid valve 21 functions as a speed controller that controls a variation of a flow rate of a processing liquid Lp that is sent from the processing liquid valve 21 to the discharge nozzle 20.

The fluid pressure measurement unit 23 is provided on a part of a fluid flow channel Cw at an upstream side of the processing liquid valve 21 and a downstream side of the fluid pressure adjustment unit 22, measures a pressure of a working fluid Lw that is supplied to the processing liquid valve 21, and transmits a result of measurement to the controller 93. For terms of “upstream” and “downstream” herein, a flow of a working fluid Lw toward the processing liquid valve 21 in a fluid flow channel Cw is a reference thereof.

The controller 93 (see FIG. 1) acquires a working fluid parameter (that is, an attenuation rate b1 as described later) that indicates behavior of a variation of a pressure of a working fluid Lw that is supplied to the processing liquid valve 21, based on a result of measurement by the fluid pressure measurement unit 23 (that is, a pressure of a working fluid Lw). Then, the controller 93 acquires correlation data between a working fluid parameter (that is, an attenuation rate b1) and an adjustment parameter for the fluid pressure adjustment unit 22 (that is, an opening degree of a fluid flow channel Cw).

FIG. 3 is a diagram for explaining a discharge stop time.

In an example as illustrated in FIG. 2, in a case where discharge of a processing liquid Lp from a discharge nozzle 20 is stopped, a controller 93 controls a fluid supply unit 28 so as to decrease a pressure of a working fluid Lw that is supplied from the fluid supply unit 28 to a processing liquid valve 21 through a fluid flow channel Cw. In such a case, it takes a reasonable time (that is, a discharge stop time) after the controller 93 emits a discharge stop signal toward the fluid supply unit 28 (see a “dispense stop” in FIG. 3) and before discharge of a processing liquid Lp from the discharge nozzle 20 is stopped completely.

This is because behavior of a variation of a pressure of a working fluid Lw (that is, a working fluid Lw that is supplied to the processing liquid valve 21) in a part of a fluid flow channel Cw between the processing liquid valve 21 and a fluid pressure adjustment unit 22 is changed, depending on an opening degree of such a fluid flow channel Cw that is adjusted by the fluid pressure adjustment unit 22. Therefore, a speed for the processing liquid valve 21 to switch a flow of a processing liquid Lp in a processing liquid flow channel Cp from on to off completely (that is, a closing speed of the processing liquid valve 21) is changed, depending on an opening degree of a fluid flow channel Cw that is adjusted by the fluid pressure adjustment unit 22.

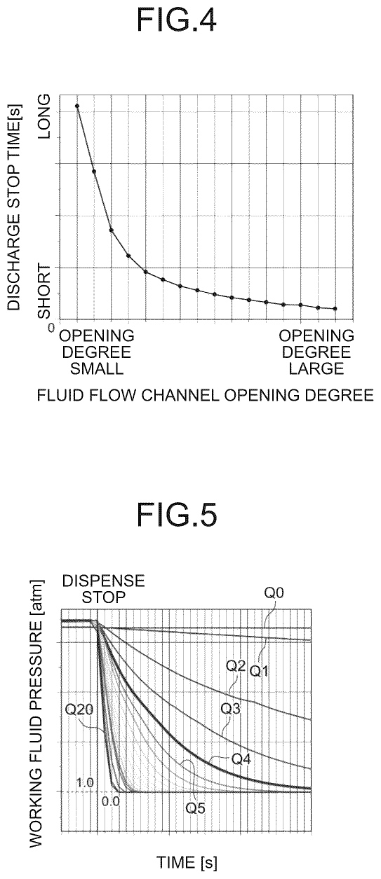

FIG. 4 is a diagram that illustrates an example of a relationship between an opening degree of a fluid flow channel Cw that is adjusted by a fluid pressure adjustment unit 22 (a horizontal axis: a “fluid flow channel opening degree”) and a discharge stop time (a vertical axis).

Concerning a horizontal axis of a graph as illustrated in FIG. 4, it indicates that an opening degree of a fluid flow channel Cw that is adjusted by the fluid pressure adjustment unit 22 is increased (that is, a substantial cross section of a fluid flow channel Cw that is adjusted by the fluid pressure adjustment unit 22 is increased) with increasing a distance from an origin of such a graph. Concerning a vertical axis of a graph as illustrated in FIG. 4, it indicates that a discharge stop time is increased with increasing a distance from an origin of such a graph. Additionally, a “discharge stop time” in FIG. 4 is acquired in such a manner that behavior of a stop of discharge of a processing liquid Lp from a discharge nozzle 20 is imaged by using a highly sensitive camera when discharge of such a processing liquid Lp from the discharge nozzle 20 is stopped and such an imaged data is confirmed by an inventor(s) of the present case.

As is clear from FIG. 4, an exponential correlation is found between an opening degree of a fluid flow channel Cw and a discharge stop time. That is, a relationship is provided in such a manner that a discharge stop time decreases exponentially with increasing an opening degree of a fluid flow channel Cw and such a discharge stop time increases exponentially with decreasing such an opening degree of a fluid flow channel Cw,

FIG. 5 is a diagram that illustrates an example of a relationship between a time passage (a “time”; a horizontal axis) and a working fluid pressure that is a result of measurement by a fluid pressure measurement unit 23 (that is, a pressure of a working fluid Lw that is supplied to a processing liquid valve 21; a vertical axis) in a case where discharge of a processing liquid Lp from a discharge nozzle 20 is stopped.

Concerning a horizontal axis of a graph as illustrated in FIG. 5, it indicates that, as a timing when a controller 93 emits a discharge stop signal toward a fluid supply unit 28 is provided as an origin (=0.0 s), a passage time after such a discharge stop signal is emitted is increased with increasing a distance from such an origin toward a right side. Concerning a vertical axis of a graph as illustrated in FIG. 5, it indicates that a pressure of a working fluid Lw increases toward an upper side.

FIG. 5 illustrates a plurality of results (“On” (where “n” is an integer that is 0 or greater and 20 or less)) that are obtained in such a manner that an opening degree of a fluid flow channel Cw is changed by a fluid pressure adjustment unit 22. In FIG. 5, it indicates a result that is obtained in a state where, as “n” that is a suffix of “On” is greater, a fluid flow channel Cw is opened more widely, and as a value of “n” increases from “Q0” to “Q20”, an opening degree of a fluid flow channel Cw is adjusted so as to increase proportionally.

In particular, “Q0” indicates a result in a case where an opening degree of a fluid flow channel Cw is “0” and such a fluid flow channel Cw is provided in a full closed state thereof. “Q20” indicates a result in a case where the fluid pressure adjustment unit 22 does not reduce an opening degree of a fluid flow channel Cw and such a fluid flow channel Cw is provided in a full open state thereof. Additionally, although display of “Q6” to “Q19” is omitted in FIG. 5, respective graph lines that are assigned with displays of “00” to “Q20” are arranged in this order in FIG. 5.

A result as illustrated in FIG. 5 is obtained by using the processing liquid valve 21 that adjust an opening degree of a processing liquid flow channel Cp so as to be decreased as a pressure of working fluid Lw that is supplied to the processing liquid valve 21 is decreased. In particular, in order to provide an opening degree of a processing liquid flow channel Cp that is adjusted by the processing liquid valve 21 as “0” (full closed), a pressure (a working fluid pressure) of a working fluid Lw that is supplied to the processing liquid valve 21 is adjusted so as to be “1.0 atm (=1.01325×10⁵ Pa)”.

As is also clear from FIG. 5, as an opening degree of a fluid flow channel Cw that is adjusted by the fluid pressure adjustment unit 22 is increased (that is, “n” that is a suffix of “On” is increased), a working fluid pressure is rapidly decreased for a shorter time. In particular, a pressure of a working fluid Lw indicates a tendency to decrease exponentially with a time passage, except a case where a fluid flow channel Cw is full closed (“Q0”).

A fitting of a result of correlation between a “time” and a “working fluid pressure” in each opening degree (see “Q0” to “Q20”) of a fluid flow channel Cw as illustrated in FIG. 5 is executed, based on an attenuation curve N(t) that is represented by formula (1) as described below.

N(t)=b0×exp(b1×t) Formula (1)

In formula (1) as described above, “b0” represents a scale (an intercept), “b1” represents an attenuation rate (a slope); “t” represents a time (an elapsed time), and “exp (b1×t)” represents an exponential function “e^{(b1×t)}”.

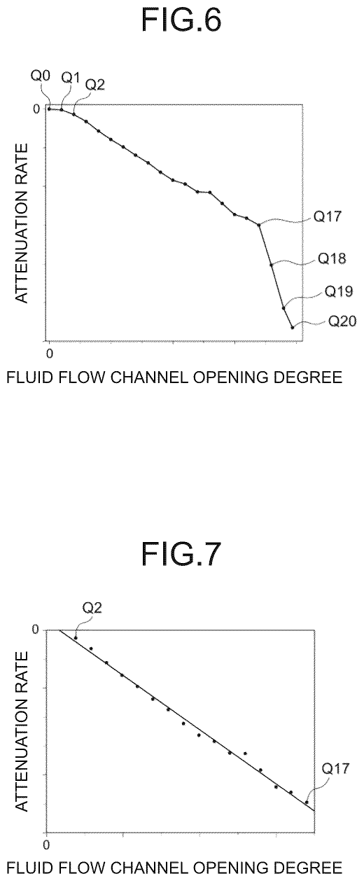

FIG. 6 is a graph that illustrates an example of a relationship between an opening degree of a fluid flow channel Cw that is adjusted by a fluid pressure adjustment unit 22 (a “fluid flow channel opening degree”; a horizontal axis) and an attenuation rate b1 (an “attenuation rate”; a vertical axis), concerning a result as illustrated in FIG. 5.

Concerning a horizontal axis of a graph as illustrated in FIG. 6, a part as indicated by “0” at a left side indicates that a fluid flow channel Cw is full closed, and it indicates that an opening degree of a fluid flow channel Cw is increased (that is, a substantial cross section of a fluid flow channel Cw that is adjusted by the fluid pressure adjustment unit 22 is increased) toward a right side. Concerning a vertical axis of a graph as illustrated in FIG. 6, a negative value is indicated below a part as indicated by “0” at an upper side and it indicates that an absolute value of an attenuation rate b1 as described above is increased toward a lower side.

Additionally, although display of “Q3” to “Q16” is omitted in FIG. 6, respective plotted points that are assigned with display of “Q0” to “Q20” in FIG. 6 are arranged in this order on a graph line.

FIG. 7 is a graph that illustrates an example of a relationship between a “fluid flow channel opening degree” and an “attenuation rate”, concerning only a result as indicated by “Q2” to “Q17” among results as illustrated in FIG. 6.

In a case where states that are close to full open and full closed of a fluid flow channel Cw where behavior of a pressure of a working fluid Lw is readily destabilized are left out of consideration, a “fluid flow channel opening degree” and an “attenuation rate” indicate a substantially linear relationship (proportional relationship), as is also clear from FIG. 7.

An attenuation rate b1 as described above represents a slope of an attenuation curve N(t) in formula (1) as described above, is an index that indicates a closing speed of a processing liquid flow channel Cp by a processing liquid valve 21, and influences a discharge stop time. As described above, an attenuation rate b1 is a parameter that is derived from “a value of a pressure of a working fluid Lw that is supplied to the processing liquid valve 21” that is a result of measurement by a fluid pressure measurement unit 23, and is capable of being temporally recorded and held as log data.

Therefore, it is possible to monitor a closing speed of the processing liquid valve 21, optimize a setting of an adjustment parameter for a fluid pressure adjustment unit 22, or allow another arithmetic process and/or state monitoring, by utilizing log data of an attenuation rate b1.

As described above, according to a liquid processing method and a discharge adjustment method that are executed by a processing unit 10 as illustrated in FIG. 2, a processing liquid Lp is sent to a discharge nozzle 20 through the processing liquid valve 21 and such a processing liquid Lp is discharged from the discharge nozzle 20 toward a substrate W. Subsequently, a processing liquid Lp that is sent to the discharge nozzle 20 through the processing liquid valve 21 is limited, depending on a discharge stop signal, so that discharge of such a processing liquid Lp from the discharge nozzle 20 is stopped. Then, the fluid pressure measurement unit 23 measures a pressure of a working fluid Lw that is supplied to the processing liquid valve 21, so that an attenuation rate b1 as described above is acquired that indicates behavior of a variation of a pressure of such a working fluid Lw. Then, correlation data between an attenuation rate b1 and an adjustment parameter (a fluid flow channel opening degree) for the fluid pressure adjustment unit 22 are acquired.

Next, a device and a method will be explained that detect behavior of a stop of discharge of a processing liquid Lp from a discharge nozzle 20, based on an intensity (an amount of light) of reflected light from a processing surface Sp of a substrate W.

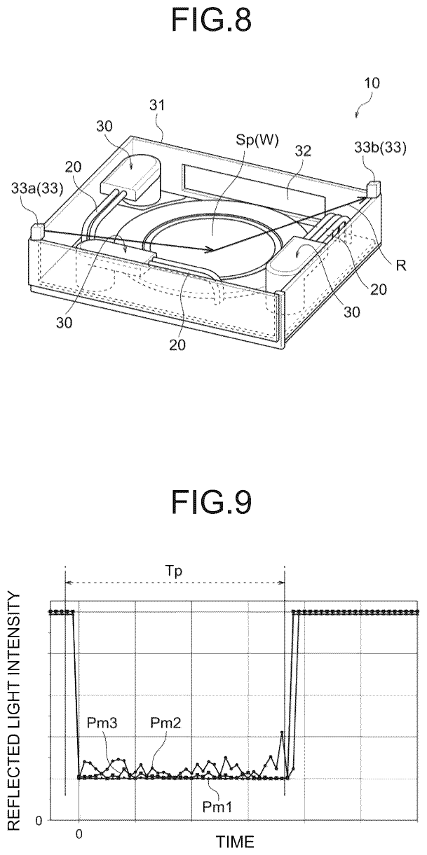

FIG. 8 is a perspective view that illustrates an example of a specific configuration of a processing unit 10.

In the processing unit 10 as illustrated in FIG. 8, a plurality of discharge unit 30 (specifically, three discharge units 30) are arranged in a processing chamber 31.

Each discharge unit 30 includes one or more discharge nozzles 20. Each discharge unit 30 is provided so as to be capable of being turned under control of a controller 93, and positions a discharge nozzle(s) 20 at a discharge position(s) for discharging a processing liquid Lp from an upper side of a substrate W toward a processing surface Sp thereof and a retraction position(s) where it/they is/are retracted from such an upper side of a substrate W. FIG. 8 illustrates a state where a discharge nozzle 20 of each discharge unit 30 is positioned at a retraction position.

An openable and closable substrate entry/exit part 32 is formed on a processing chamber 31. The substrate entry/exit part 32 is opened or closed under control of the controller 93 (see FIG. 1). A substrate W is moved between an inside and an outside of the processing chamber 31 through the substrate entry/exit part 32 in an open state thereof, and is supported by a substrate support unit (where illustration thereof is omitted) so as to be rotatable in the processing chamber 31.

The processing chamber 31 is further provided with a light measurement unit 33 that includes a light emitting unit 33a and a light receiving unit 33b. Under control of the controller 93, a processing surface Sp of a substrate W that is supported by a substrate support unit in the processing chamber 31 is irradiated with light (detection light) from the light emitting unit 33a and the light receiving unit 33b receives reflected light R from such a processing surface Sp so as to detect an intensity of such reflected light R temporally and repeatedly. Herein, detection light (that is, reflected light R) is laser light, LED light, or any other light. A result of detection of an intensity of reflected light R that is thus acquired is sent from the light measurement unit 33 (in particular, the light receiving unit 33b) to the controller 93.

The controller 93 determines a discharge state of a processing liquid Lp from the discharge nozzle 20 at a time when discharge of such a processing liquid Lp from the discharge nozzle 20 is stopped, based on a result of detection of an intensity of reflected light R that is acquired by the light measurement unit 33. An intensity of reflected light R in a case where a processing liquid Lp is not present on a processing surface Sp of a substrate W is higher than an intensity of reflected light R in a case where such a processing liquid Lp is present on such a processing surface Sp. Hence, it is possible to determine a state (for example, a quantity) of a processing liquid Lp on a processing surface Sp, based on a detected intensity of reflected light R, and eventually, it is possible to determine a discharge state of such a processing liquid Lp from the discharge nozzle 20,

FIG. 9 is a diagram that illustrates an example of a relationship between a time passage (a “time”; a horizontal axis) and an intensity of reflected light R that is acquired by a light measurement unit 33 (a “reflected light intensity”; a vertical axis).

Concerning a horizontal axis of a graph as illustrated in FIG. 9, it indicates that a longer time has passed with increasing a distance from a position of “0” toward a right side. Concerning a vertical axis of a graph as illustrated in FIG. 9, it indicates that reflected light R with a higher intensity is detected by the light measurement unit 33 (that is, a light receiving unit 33b) with increasing a distance from a position of “0” toward an upper side.

FIG. 9 illustrates results Pm1 to Pm3 where a frequencies (detection time intervals) for the light measurement unit 33 to detect and acquire an intensity of reflected light R are different from one another. A detection time interval of result Pm1 is less than detection time intervals of results Pm2, Pm3, and is, for example, 250 μs. A detection time interval of result Pm2 is greater than detection time intervals of results Pm1, Pm3, and is, for example, 1 ms, A detection time interval of result Pm3 is greater than a detection time interval of result Pm1 and less than a detection time interval of Pm2, and is, for example, 500 μs.

Each of results Pm1 to Pm3 as illustrated in FIG. 9 is based on a result of detection of reflected light R that is acquired by the light measurement unit 33 in a state where a substrate W is rotated by a substrate support unit. That is, each of results Pm1 to Pm3 is obtained in a situation where a processing liquid Lp on a processing surface Sp is gradually scattered from a substrate W by rotation of such a substrate W.

FIG. 9 illustrates a time range Tp where a processing liquid Lp is discharged from a discharge nozzle 20 toward a processing surface Sp of a substrate W.

As is also clear from FIG. 9, an intensity of reflected light R from a processing surface Sp that is detected by the light measurement unit 33 is decreased so as to correspond to a time range Tp where a processing liquid Lp is discharged from the discharge nozzle 20 toward such a processing surface Sp of a substrate W. Hence, it is possible to evaluate a discharge state of a processing liquid Lp from the discharge nozzle 20 at a time when discharge of such a processing liquid Lp from the discharge nozzle 20 is stopped, based on a result of detection of an intensity of reflected light R from a processing surface Sp that is acquired by the light measurement unit 33,

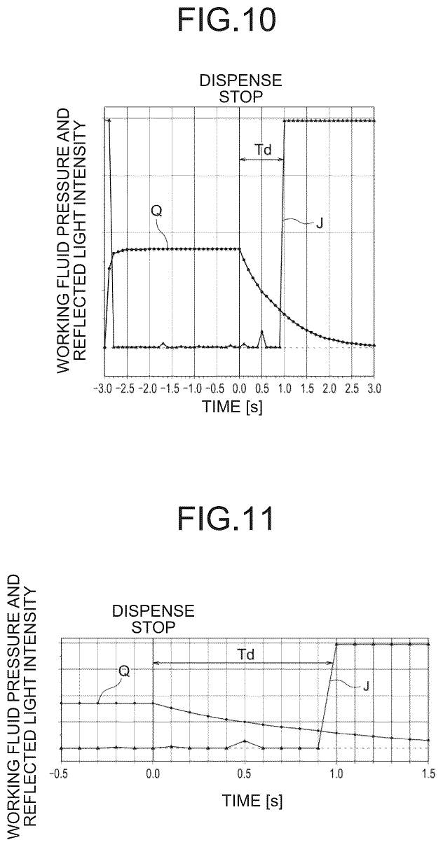

FIG. 10 and FIG. 11 are diagrams that illustrate an example of a relationship between a time passage (a “time”; a horizontal axis), and a working fluid pressure Q and an intensity J of reflected light R (“a working fluid pressure and a reflected light intensity”; a vertical axis) in a case where discharge of a processing liquid Lp from a discharge nozzle 20 is stopped. FIG. 11 illustrates time ranges before and after discharge of a processing liquid Lp from the discharge nozzle 20 is stopped completely, and a width of a horizontal axis (a “time”) per unit time is greater than that of FIG. 10.

A working fluid pressures Q in FIG. 10 and FIG. 11 is based on a result of measurement by a fluid pressure measurement unit 23 (see FIG. 2), similarly to a result as illustrated in FIG. 5 as described above (in particular, a result as indicated by “Q4”), and represents a pressure of a working fluid Lw that is supplied to a processing liquid valve 21. On the other hand, an intensity J of reflected light R in FIG. 10 and FIG. 11 is a result of measurement by a light measurement unit 33 (see FIG. 8) and represents an intensity of reflected light R that is received by a light receiving unit 33b.

Concerning a horizontal axis (a time) in FIG. 10 and FIG. 11, a timing when a controller 93 emits a discharge stop signal toward a fluid supply unit 28 (see a “dispense stop” in FIG. 10 and FIG. 11) is set at “0.0 s”.

An inventor(s) of the present case has/have confirmed a state of discharge of a processing liquid Lp from the discharge nozzle 20, based on imaging data of a highly sensitive camera. As a result, a discharge state of a processing liquid Lp from the discharge nozzle 20 (specifically, a state of a liquid column that extends from the discharge nozzle 20) is rapidly changed on an order of 0.01 s (=10 ms) around an elapsed time of “0.8 s”.

Then, an intensity J of reflected light R that is measured by the light measurement unit 33 starts to rise rapidly, depending on a timing when discharge of a processing liquid Lp from the discharge nozzle 20 is stopped completely. Additionally, strictly, a timing when an intensity J of reflected light R that is measured by the light measurement unit 33 starts to rise is delayed from a timing when discharge of a processing liquid Lp from the discharge nozzle 20 is stopped completely.

As is also clear from results as illustrated in FIG. 10 and FIG. 11 as described above, it takes a reasonable time (that is, a discharge stop time (see FIG. 3)) after the controller 93 emits a discharge stop signal toward the fluid supply unit 28 and before discharge of a processing liquid Lp from the discharge nozzle 20 is stopped completely.

A correlation is provided between an index time (that is, a delay time Td) that indicates a time interval after a discharge stop signal is emitted and before an intensity J of reflected light R rises rapidly, and a time (a discharge stop time) when discharge of a processing liquid Lp from the discharge nozzle 20 is stopped completely.

For example, a delay time Td is capable of being represented by a time period after a discharge stop signal is emitted and before an intensity J of reflected light R that is detected by the light measurement unit 33 exceeds an intensity reference value. Herein, an intensity reference value is not limited, is capable of being appropriately set by a manager, and is set at an intensity of reflected light R that is detected by the light measurement unit 33 in a state where processing liquid Lp is not present on a processing surface Sp of a substrate W, or less.

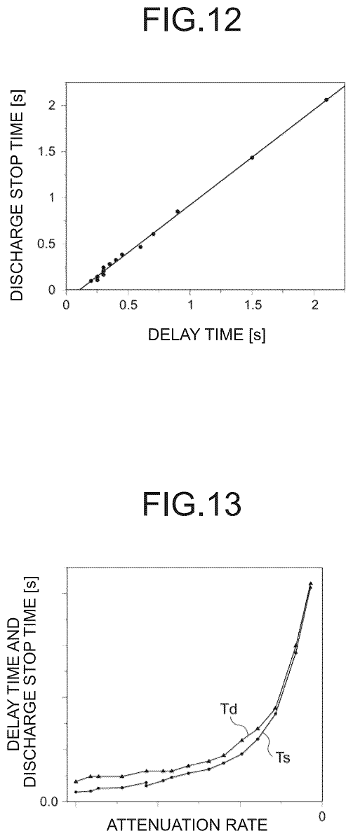

FIG. 12 is a diagram that illustrates an example of a relationship between a delay time Td (a horizontal axis) and a discharge stop time (a vertical axis).

In FIG. 12, a “discharge stop time” is acquired in such a manner that behavior of a stop of discharge of a processing liquid Lp from a discharge nozzle 20 at a time when discharge of such a processing liquid Lp from the discharge nozzle 20 is stopped is imaged by using a highly sensitive camera and such imaging data are confirmed by an inventor(s) of the present case. A “delay time” is acquired based on a result of detection by a light measurement unit 33.

As is also clear from FIG. 12, a “delay time” and a “discharge stop time” indicate a substantially linear relationship (a proportional relationship). Therefore, a “delay time” is available as an index that indicates a “discharge stop time”.

Additionally, in a result as illustrated in FIG. 12, an RMSE (Root-Mean-Square Error) is slightly large. However, a measurement time interval for the light measurement unit 33 is determined so as to be similar to a time order (10 ms in an example as described above) of a liquid column change in the discharge nozzle 20 (by setting, for example, such a measurement time interval at 10 ms), so that it is possible to reduce an RMSE sufficiently.

FIG. 13 is a diagram that illustrates an example of a relationship between an attenuation rate b1 (a horizontal axis) in formula (1) as described above, and a delay time Td and a discharge stop time Ts (a vertical axis).

In FIG. 13, an “attenuation rate” is acquired based on a result of detection by a fluid pressure measurement unit 23 and a “delay time” and a “discharge stop time” are obtained similarly to those of FIG. 12 as described above.

Concerning a horizontal axis of a graph as illustrated in FIG. 13, a left side of a part that is indicated by “0” at a right side indicates a negative value and it indicates that an absolute value of an attenuation rate b1 is increased toward a left side. Concerning a vertical axis of a graph as illustrated in FIG. 13, it indicates that a delay time Td and a discharge stop time Ts are increased toward an upper side from “0.0 s” at a lower side.

As is also clear from FIG. 13, each of a delay time Td and a discharge stop time Ts has a unique correlation (for example, an exponential correlation) with respect to an attenuation rate b1.

As described above, according to a liquid processing method and a discharge adjustment method that are executed by a processing unit 10 as illustrated in FIG. 8, a step of sending a processing liquid Lp to a discharge nozzle 20 through a processing liquid valve 21 so as to discharge such a processing liquid Lp from the discharge nozzle 20 toward a processing surface Sp of a substrate W is executed. Subsequently, a step of limiting a processing liquid Lp that is sent to the discharge nozzle 20 through the processing liquid valve 21, depending on a discharge stop signal, so as to stop discharge of such a processing liquid Lp from the discharge nozzle 20 is executed. On the other hand, a processing surface Sp is irradiated with detection light, an intensity of reflected light R from such a processing surface Sp is detected temporally, and a discharge state of a processing liquid Lp from the discharge nozzle 20 at a time when discharge of such a processing liquid Lp from the discharge nozzle 20 is stopped is determined based on a result of detection of an intensity of reflected light R.

For example, it is also possible to determine a discharge state of a processing liquid Lp from the discharge nozzle 20 at a time when discharge of such a processing liquid Lp from the discharge nozzle 20 is stopped, based on a result of detection of an intensity of reflected light R at a point of time when a determination reference time has passed from a timing when a discharge stop signal is emitted. Herein, a determination reference time is not limited and is capable of being appropriately set by a manager, and a determination reference time may be set at, for example, a time period of a delay time Td or longer as described above.

Next, an application example of “a technique that detects behavior of a stop of discharge of a processing liquid from a discharge nozzle” as described above will be explained.

Each application example that will be explained below is executed based on a technique as described above and a repeated explanation of a technical content as already described will be omitted. Furthermore, concerning a technique common to application examples, a repeated explanation of a technical content that is explained for a previous application example will be omitted in an application example that is described later. Furthermore, application examples may be partly or entirely combined with one another appropriately.

### First Application Example

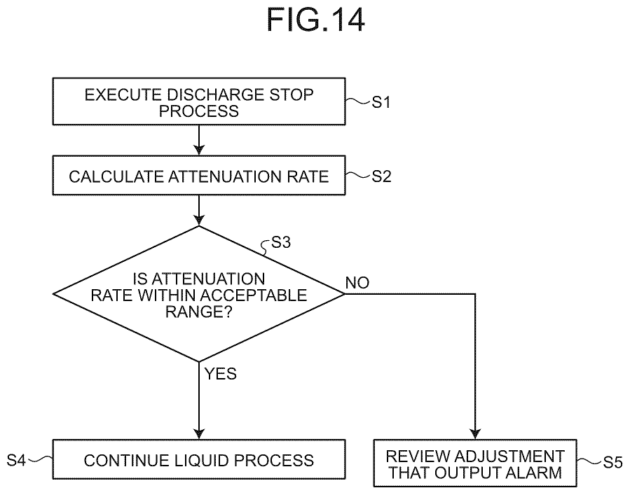

FIG. 14 is a diagram that illustrates a process flow of a first application example.

In the present example, whether or not an adjustment parameter for a fluid pressure adjustment unit 22 (an opening degree of a fluid flow channel Cw) is suitable is determined based on “an attenuation rate b1 of a pressure of a working fluid Lw” at a time when discharge of a processing liquid Lp from a discharge nozzle 20 is stopped.

That is, first, a pressure of a working fluid Lw that is supplied from a fluid supply unit 28 to a fluid flow channel Cw is adjusted under control of a controller 93, so that a process of stopping discharge of a processing liquid Lp from the discharge nozzle 20 (a discharge stop process) is executed (S1 in FIG. 14).

During such a discharge stop process, a pressure of a working fluid Lw that is supplied to a processing liquid valve 21 is measured by a fluid pressure measurement unit 23 and a result of measurement is sent from the fluid pressure measurement unit 23 to the controller 93.

Then, the controller 93 calculates an attenuation rate b1 of a pressure of a working fluid Lw during executing of a discharge stop process, based on a result of measurement by the fluid pressure measurement unit 23 (S2). Specifically, fitting of a result of a correlation between a “time” and a “working fluid pressure” that is acquired based on a result of measurement by the fluid pressure measurement unit 23 (see FIG. 5) is executed based on an attenuation curve N(t) that is represented by formula (1) as described above, so as to calculate an attenuation rate b1.

Then, the controller 93 determines whether or not a calculated attenuation rate b1 is within an acceptable range (S3). Herein, an acceptable range is capable of being determined based on any method and may be determined based on, for example, correlation data that are acquired previously. That is, a discharge state of a processing liquid Lp from the discharge nozzle 20 at a time when discharge of such a processing liquid Lp from the discharge nozzle 20 is stopped may be determined, based on whether or not a calculated attenuation rate b1 is included in an acceptable range that is determined based on previous correlation data.

As an example, “an initial adjustment value of an opening degree of a fluid flow channel Cw” that corresponds to “an attenuation rate b1” is obtained based on correlation data (normal correlation data) between “an opening degree of a fluid flow channel Cw that is adjusted by the fluid pressure adjustment unit 22” and “an attenuation rate b1” that are acquired at a time of a normal operation of a processing unit 10. Then, a range of an attenuation rate b1 that corresponds to a range of P18 (where “P1” is any value) of an initial adjustment value is acquired based on normal correlation data and may be set so as to be an “acceptable range” that is used for determination as described above (S3).

In determination as described above, in a case where it is determined that an attenuation rate b1 is within an acceptable range (Yes at S3), a liquid process is continued and a processing liquid Lp is discharged from the discharge nozzle 20 toward a substrate W as needed, under control of the controller 93 (S4).

On the other hand, in a case where it is determined that an attenuation rate b1 is not within an acceptable range (No at S3), an alarm is output so as to encourage a manager to execute a review (maintenance) of adjustment of a device setting under control of the controller 93 (S5).

A specific mode of an alarm is not limited. Typically, an alarm message is displayed in a display (where illustration thereof is omitted) or an alarm tone is sounded from a sound device (where illustration thereof is omitted), so that an alarm is issued toward a manager.

As a manager perceives such an alarm, he/she reviews adjustment of a device setting of the processing unit 10, Typically, an adjustment parameter (an opening degree of a fluid flow channel Cw) for the fluid pressure adjustment unit 22 is adjusted in such a manner that an attenuation rate b1 falls within an acceptable range. Thus, a setting of an adjustment parameter for the fluid pressure adjustment unit 22 is adjusted, based on a result of determination of a discharge state of a processing liquid Lp from the discharge nozzle 20 at a time when discharge of such a processing liquid Lp from the discharge nozzle 20 is stopped.

As explained above, an adjustment parameter (an opening degree of a fluid flow channel Cw) for the fluid pressure adjustment unit 22 is adjusted based on an attenuation rate b1, in light of previous correlation data between an attenuation rate b1 (a working fluid parameter) and such an adjustment parameter (an opening degree of a fluid flow channel Cw) for the fluid pressure adjustment unit 22. That is, a step of determining a discharge state of a processing liquid Lp from the discharge nozzle 20 at a time when discharge of such a processing liquid Lp from the discharge nozzle 20 is stopped is executed, based on whether or not an attenuation rate b1 is included in an acceptable range.

As described above, a variation of a discharge stop time is monitored, based on “log data of an attenuation rate b1 of a pressure of a working fluid Lw” that is obtained from a result of measurement by the fluid pressure measurement unit 23, so that it is possible to execute management of the processing liquid valve 21, and eventually, digital management of discharge of a processing liquid in the discharge nozzle 20.

### Second Application Example

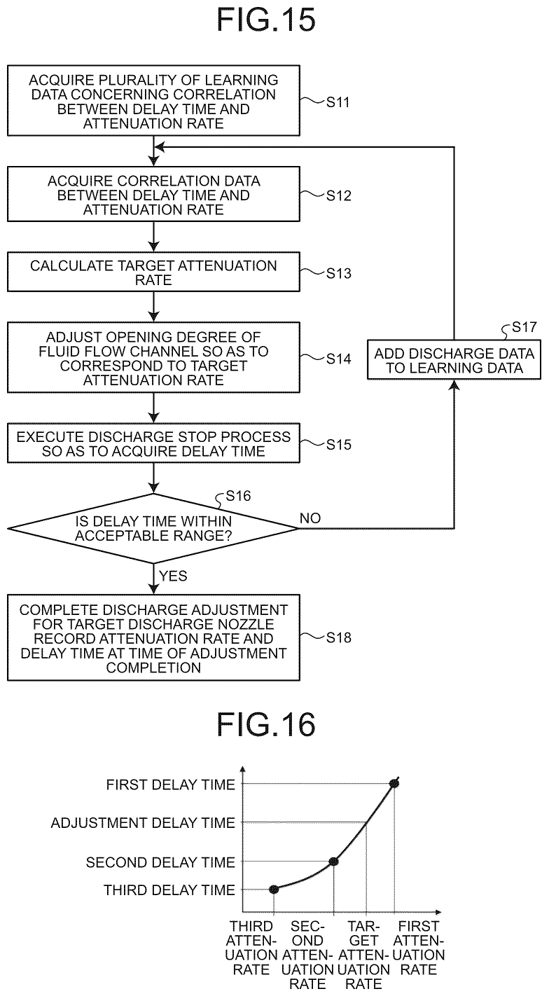

FIG. 15 is a diagram that illustrates a process flow of a second application example. FIG. 16 is a diagram that illustrates an example of a correlation between an attenuation rate b1 (a horizontal axis) and a delay time Td (a vertical axis).

In the present example, a discharge state of a processing liquid Lp from a discharge nozzle 20 at a time when discharge of such a processing liquid Lp from the discharge nozzle 20 is stopped is determined, based on a delay time Td, so that an adjustment parameter for a fluid pressure adjustment unit 22 is adjusted. Thereby, a discharge stop time is adjusted optimally.

That is, first, a controller 93 acquires a plurality of learning data concerning a correlation between a delay time Td and an attenuation rate b1 (S11 in FIG. 15).

Specifically, a discharge stop process is executed multiple times and in each discharge stop process, a delay time Td and an attenuation rate b1 are acquired and stored in a storage as a record. For example, a first delay time and a first attenuation rate are acquired in a first discharge stop process, a second delay time and a second attenuation rate are acquired in a second discharge stop process, and a third delay time and a third attenuation rate are acquired in a third discharge stop process.

Then, the controller 93 acquires correlation data between a delay time Id and an attenuation rate b1 from a plurality of acquired learning data (S12). For example, as illustrated in FIG. 16, a correlation data line between a delay time Td and an attenuation rate b1 are acquired from plotted data that are based on first to third attenuation rates and first to third delay times. Herein, a correlation data line is capable of being derived based on any technique and may be derived by, for example, fitting that uses a known model formula (model curve).

Then, the controller 93 calculates an attenuation rate that corresponds to an adjustment delay time (that is, a target attenuation rate) (S13).

Herein, an adjustment delay time is, for example, a delay time that corresponds to a “targeted discharge stop time” that is set by a manager and such a delay time is capable of being acquired based on “correlation data between a delay time Td and a discharge stop time (see FIG. 12)”. Then, a target attenuation rate that corresponds to an adjustment delay time is acquired, based on “correlation data between a delay time Td and an attenuation rate b1 (see FIG. 16)” that are acquired at a process step S12 as described above.

Then, an opening degree of a fluid flow channel Cw is adjusted so as to correspond to a target attenuation rate (S14). That is, an opening degree of a fluid flow channel Cw that corresponds to a target attenuation rate is acquired, based on “correlation data between an opening degree of a fluid flow channel Cw and an attenuation rate b1 (see FIG. 6 and FIG. 7)”, and an adjustment parameter for the fluid pressure adjustment unit 22 is adjusted so as to realize such an opening degree of a fluid flow channel Cw.

The present process step S14 may be partially or entirely executed under control of the controller 93. For example, both acquisition of an adjustment parameter (an opening degree of a fluid flow channel Cw) that corresponds to a target attenuation rate and adjustment of an adjustment parameter for the fluid pressure adjustment unit 22 may mechanically be executed under control of the controller 93. Alternatively, while acquisition of an adjustment parameter (an opening degree of a fluid flow channel Cw) that corresponds to a target attenuation rate is executed by the controller 93, adjustment of an adjustment parameter for the fluid pressure adjustment unit 22 may manually be executed by a manager.

Subsequently, a discharge stop process is executed under control of the controller 93, so that a delay time Td is acquired, based on a result of detection of a light measurement unit 33 (see FIG. 8) (S15), That is, a delay time Td that corresponds to an adjustment parameter (an opening degree of a fluid flow channel Cw) for the fluid pressure adjustment unit 22 that is adjusted at the process step S14 as described above is acquired based on a result of detection of the light measurement unit 33.

Then, the controller 93 determines whether or not a delay time Td that is acquired at the process step S15 as described above is within an acceptable range (S16). That is, a discharge state of a processing liquid Lp from the discharge nozzle 20 at a time when discharge of such a processing liquid Lp from the discharge nozzle 20 is stopped is determined based on whether or not a delay time Td is included in an acceptable range.

Herein, an acceptable range is not limited and is capable of being set by, for example, a manager. For example, it is possible to determine an acceptable range, with reference to an adjustment delay time (see FIG. 16) that is used at a time when a target attenuation rate is calculated at the process step S13 as described above. As an example, a range of ±P2% (where “P2” is any value) of an adjustment delay time may be set so as to be an “acceptable range” that is used at the present process step S16.

In a case where it is determined that a delay time Td is within an acceptable range (Yes at S16), adjustment concerning discharge from a target discharge nozzle 20 is completed and an attenuation rate b1 and a delay time Td at a time of completion of adjustment are stored in a storage under control of the controller 93.

Then, adjustment of discharge for the discharge nozzle 20 that is a next adjustment target is executed based on process steps S11 to S18 as described above, as needed. Thus, adjustment of discharge for a plurality of discharge nozzles 20 is executed so as to reduce a difference between discharge characteristics of a processing liquid Lp from the discharge nozzles 20, so that it is possible to execute uniform discharge of a processing liquid Lp from the plurality of discharge nozzles 20.

On the other hand, in a case where it is determined that a delay time Td is not within an acceptable range (No at S16), the controller 93 adds discharge data that are used at a time of determination at the process step S16 to learning data (S17) and executes the process step S12 as described above again.

Specifically, a target attenuation rate that is calculated at the process step S13 as described above and a delay time Td that is acquired at the process step S15 as described above, as discharge data, are newly added as learning data that indicate a correlation between an attenuation rate b1 and a delay time Td. Thereby, correlation data where such newly added learning data are reflected (that is, updated correlation data) are acquired at the process step S12 that is subsequently executed again, and the subsequent process steps S13 to S13 are executed based on such updated correlation data.

As a result, setting of an adjustment parameter (an opening degree of a fluid flow channel Cw) for the fluid pressure adjustment unit 22 is adjusted, based on a result of determination of a discharge state of processing liquid Lp from the discharge nozzle 20 at a time when discharge of such a processing liquid Lp from the discharge nozzle 20 is stopped.

### Third Application Example

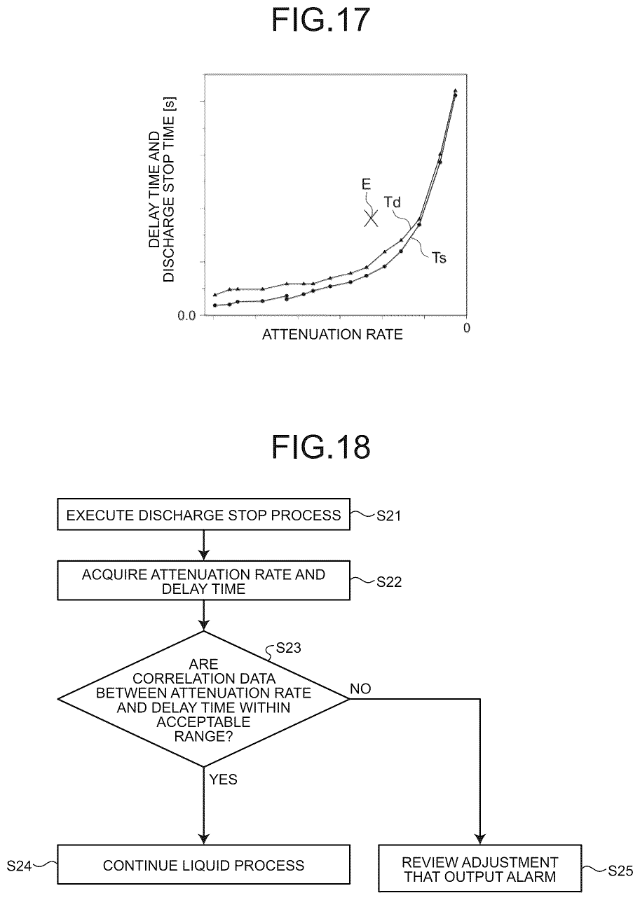

FIG. 17 is a diagram that illustrates an example of a relationship between an attenuation rate b1 (a horizontal axis), and a delay time Td and a discharge stop time Ts (a vertical axis). FIG. 18 is a diagram that illustrates a process flow of a third application example.

In the present example, “normal correlation data between an attenuation rate b1 and a delay time Td” that are acquired preliminarily and “correlation data between an attenuation rate b1 and a delay time Td” that are acquired actually are compared, so that presence or absence of abnormality in a processing liquid valve 21 and a fluid pressure adjustment unit 22 is determined. Thereby, it is possible to detect failure of the processing liquid valve 21 and the fluid pressure adjustment unit 22.

In a case where a discharge stop process is executed normally and suitably, a correlation between an attenuation rate b1 of a pressure of working fluid Lw that is supplied to the processing liquid valve 21, a delay time Td, and a discharge stop time Ts is represented by, for example, a graph line (a normal graph line) as illustrated in FIG. 17.

On the other hand, an attenuation rate b1, a delay time Td, and a discharge stop time Ts that are acquired in a case where abnormality is caused in a discharge stop process deviates from such a normal graph line (see reference sign “E” in FIG. 17). Therefore, in a case where “correlation data between an attenuation rate b1 and a delay time Td” that are acquired actually deviate from a normal graph line greatly, it is assumed that abnormality such as failure is caused in the processing liquid valve 21 and/or the fluid pressure adjustment unit 22.

Specifically, first, the processing liquid valve 21 is operated under control of a controller 93 so as to execute a discharge stop process of stopping discharge of a processing liquid Lp from a discharge nozzle 20 (S21 in FIG. 18).

Then, the controller 93 acquires an attenuation rate b1 and a delay time Td, based on a result of detection of a fluid pressure measurement unit 23 and a result of detection of a light measurement unit 33 that are obtained during executing of a discharge stop process (S22).

Then, the controller 93 determines whether or not correlation data between an attenuation rate b1 and a delay time Td that are thus acquired are within an acceptable range (S23). That is, a discharge state of a processing liquid Lp from the discharge nozzle 20 at a time when discharge of such a processing liquid Lp from the discharge nozzle 20 is stopped is determined, based on whether or not combination data of an attenuation rate b1 and a delay time Td are included in an acceptable range.

Herein, an acceptable range is not limited and is capable of being set by, for example, a manager. For example, it is possible to determine an acceptable range, based on a distance (for example, a shortest distance) on a graph between “a normal graph line concerning an attenuation rate b1 and a delay time Td” that is acquired preliminarily and “a plotted position E of an attenuation rate b1 and a delay time Td that are acquired”.

In determination as described above, in a case where it is determined that correlation data between an attenuation rate b1 and a delay time Td are within an acceptable range (Yes at S23), a liquid process is continued under control of the controller 93 and a processing liquid Lp is discharged from the discharge nozzle 20, as needed (S24).

On the other hand, in a case where it is determined that correlation data between an attenuation rate b1 and a delay time Td that are acquired deviate from an acceptable range (No at S23), an alarm is issued under control of the controller 93 (S25). A manager perceives abnormality in the processing liquid valve 21 by such an alarm, so that a need of a review (maintenance) of adjustment of the fluid pressure adjustment unit 22 is encouraged.

### Fourth Application Example

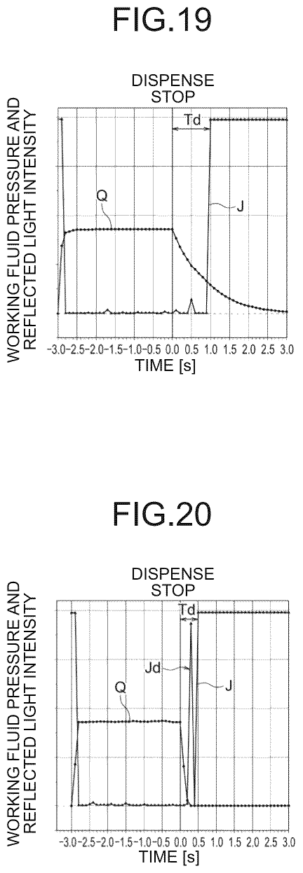

FIG. 19 is a diagram that illustrates an example of a relationship between a time passage (a horizontal axis), and a working fluid pressure Q and an intensity J of reflected light R (a vertical axis) in a case where discharge of a processing liquid Lp from a discharge nozzle 20 is stopped, and a case where dropping of a liquid droplet(s) from the discharge nozzle 20 that is not particularly intended is absent. FIG. 20 is a diagram that illustrates an example of a relationship between a time passage (a horizontal axis), and a working fluid pressure Q and an intensity J of reflected light R (a vertical axis) in a case where discharge of a processing liquid Lp from a discharge nozzle 20 is stopped, and a case where dropping of a liquid droplet(s) from the discharge nozzle 20 that is not particularly intended is present.

In a discharge stop time (see FIG. 3) when a process of stopping discharge of a processing liquid Lp from the discharge nozzle 20 is executed, as a liquid droplet(s) of such a processing liquid Lp from the discharge nozzle 20 drop(s) unintentionally so as to land on a processing surface Sp of a substrate W, an intensity of reflected light R from such a processing surface Sp is influenced therewith.

For example, until just before such a liquid droplet(s) land(s) on a processing surface Sp, a quantity of a processing liquid Lp on such a processing surface Sp is gradually decreased by rotation of a substrate W, so that an intensity of reflected light R that is detected by a light measurement unit 33 indicates a tendency to rise. In such a situation, as a liquid droplet(s) of a such a processing liquid Lp land(s) on such a processing surface Sp unintentionally, an intensity of reflected light R that is detected by the light measurement unit 33 indicates a tendency to once lower and subsequently rise again (see reference sign “Jd” in FIG. 20).

Thus, as a liquid droplet(s) of a processing liquid Lp from the discharge nozzle 20 drop(s) unintentionally during executing of a discharge stop process, an intensity of reflected light R that is detected by the light measurement unit 33 indicates unstable behavior.

Therefore, a controller 93 analyzes an intensity of reflected light R from a processing surface Sp of a substrate W, based on a result of detection of the light measurement unit 33 that is acquired during executing of a discharge stop process, so as to monitor presence or absence of dropping of a liquid droplet(s) of a processing liquid Lp from the discharge nozzle 20.

Specifically, a discharge state of a processing liquid Lp from the discharge nozzle 20 at a time when discharge of such a processing liquid Lp from the discharge nozzle 20 is stopped is determined, based on a result of detection of an intensity of reflected light R during passing of a determination reference time from a timing when a discharge stop signal is emitted. Herein, a determination reference time is not limited and is capable of being appropriately set by a manager. For example, a determination reference time may have a length of a discharge stop time or longer, so as to cover a whole after a timing when a discharge stop signal is emitted and before discharge of a processing liquid Lp from the discharge nozzle 20 is stopped completely.

A variety of modes of a liquid droplet(s) that drop(s) from discharge nozzle 20 unintentionally are provided, so that “a mode of a turbulence of an intensity of reflected light R that is detected by the light measurement unit 33” that is caused by such dropping of a liquid droplet(s) is also not constant. Hence, it is preferable for the controller 93 to execute analysis based on a magnitude of an intensity, behavior of a temporal change, and/or any other viewpoint of reflected light R that is/are acquired by the light measurement unit 33, so as to monitor presence or absence of dropping of a liquid droplet(s) of a processing liquid Lp from the discharge nozzle 20.

In a case where unintended dropping of a liquid droplet(s) from the discharge nozzle 20 is detected as described above, it is possible for the controller 93 to execute any process. Typically, an alarm is issued, or information that indicates a fact of unintended dropping of a liquid droplet(s) and/or information of identification of a substrate W where such a liquid droplet(s) land(s) is/are stored in a storage as a record(s).

It is possible for a manager to perceive a fact of unintended dropping of a liquid droplet(s) from the discharge nozzle 20, based on such an alarm and/or information that is recorded in a storage, so that it is possible to execute maintenance, etc., of a processing liquid valve 21 and a fluid pressure adjustment unit 22 appropriately, Additionally, such recorded information may be read from a storage as needed and be used for any other process.

Additionally, even if unintended dropping of microscopic liquid droplet(s) from the discharge nozzle 20 is caused substantially several times (for example, substantially 1 to 2 times), it may not particularly be problematic for a liquid process. If an alarm is issued in such a case, an originally unwanted interruption of a liquid process may be caused so as to rather interfere with such a liquid process.

Hence, the controller 93 may execute control so as to issue an alarm in a case where a number of times that an intensity of reflected light R that is detected by the light measurement unit 33 exceeds a determination reference value exceeds a determination reference number of times, after a timing when a discharge stop signal is emitted and before a determination reference time passes.

Herein, a determination reference value and a determination reference number of times are values that are capable of being appropriately set by a manager and it is preferable to determine such a determination reference value and a determination reference number of times based on a value and a number of times that do not cause a substantial adverse effect on a liquid process. As a determination reference value is set suitably, an alarm is not issued in a case where a quantity of an unintended liquid droplet(s) from the discharge nozzle 20 is a minute quantity that is not problematic, so that it is possible to prevent interfering with a liquid process. Similarly, as a determination reference number of times is set suitably, an alarm is not issued in a case where a number of times that a droplet(s) is/are unintentionally dropped from the discharge nozzle 20 is a number of times that is substantially not problematic, so that it is possible to prevent interfering with a liquid process.

### Fifth Application Example

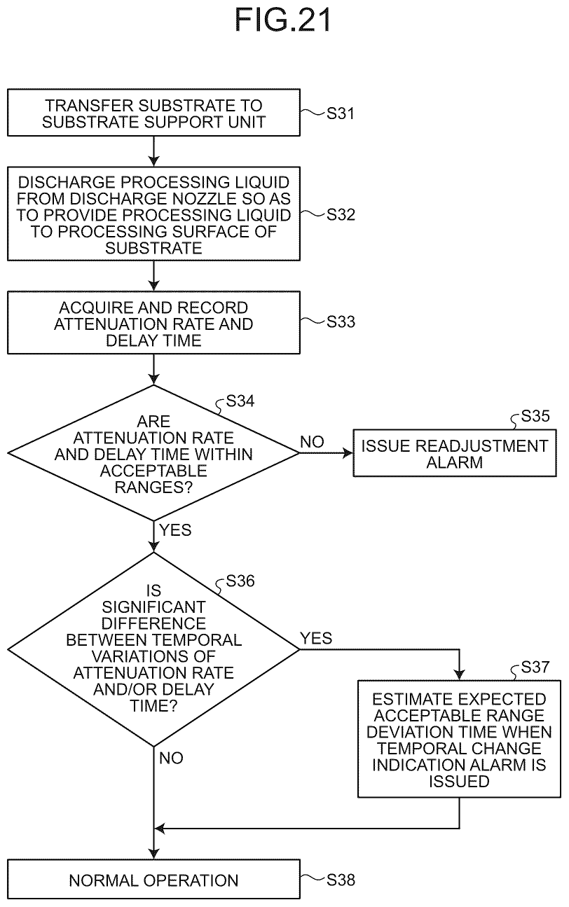

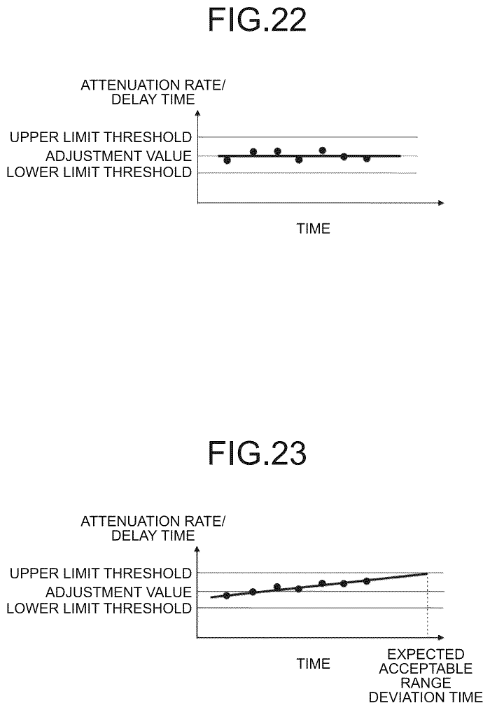

FIG. 21 is a diagram that illustrates a process flow of a fifth application example, FIG. 22 is a diagram that illustrates an example of a relationship between a time passage (a horizontal axis) and an attenuation rate b1/a delay time Td (a vertical axis), and in particular, illustrates a case where a significant difference is absent between temporal variations of an attenuation rate and a delay time. FIG. 23 is a diagram that illustrates an example of a relationship between a time passage (a horizontal axis) and an attenuation rate b1/a delay time Td (a vertical axis), and in particular, illustrates a case where a significant difference is present between temporal variations of an attenuation rate and a delay time.

Concerning vertical axes of FIG. 22 and FIG. 23, display of “an attenuation rate/a delay time” indicates that a parameter that is assigned to a vertical axis is “an attenuation rate” or “a delay time”.

In the present example, temporal changes of a processing liquid valve 21 and a fluid pressure adjustment unit 22 are evaluated in addition to determining necessity of readjustment of an adjustment parameter for the fluid pressure adjustment unit 22 based on an attenuation rate b1 and a delay time Td.

That is, a substrate W is transferred to a substrate support unit in a processing unit 10 (S31 in FIG. 21), and a processing liquid Lp is discharged from a discharge nozzle 20, so that such a processing liquid Lp is provided to a processing surface Sp of a substrate W (S32). When a processing liquid Lp is provided to a processing surface Sp, a substrate W is rotated by a substrate support unit, so that such a processing liquid Lp is gradually scattered from such a processing surface Sp by rotation of such a substrate W. Additionally, after a substrate W is supported by a substrate support unit and before a processing liquid Lp is provided to a processing surface Sp, an output setting of a sensor (a wafer sensor) that is installed in the processing unit 10 may be adjusted.

Subsequently, when a discharge stop process is executed as described above, under control of a controller 93, an attenuation rate b1 and a delay time Td as described above are acquired and an acquired attenuation rate b1 and delay time Td are saved and recorded in a storage (S33).

Subsequently, the controller 93 determines whether or not an attenuation rate b1 and a delay time Td are within acceptable ranges (S34). Herein, a specific determination method thereof is not limited and whether or not each of an attenuation rate b1 and a delay time Td is within an acceptable range may be determined or whether or not a combination data of such an attenuation rate b1 and a delay time Td are within an acceptable range may be determined (see FIG. 17).

In a case where an attenuation rate b1 and a delay time Td are not within an acceptable range (No at S34), an alarm (a readjustment alarm) is issued under control of the controller 93 (S35), so that a manager is encouraged to execute adjustment, etc., (maintenance) of the processing liquid valve 21 and/or the fluid pressure adjustment unit 22.

In a case where an attenuation rate b1 and a delay time Td are within an acceptable range (Yes at S34), the controller 93 determines whether or not a significant difference is present between temporal variations of an attenuation rate b1 and/or a delay time Td (S36).

In a case where a significant difference is absent between temporal variations of an attenuation rate b1 and/or a delay time Td, actual values that are temporally acquired multiple times concerning such an attenuation rate b1 and/or a delay time Td are dispersed without a bias near an adjustment value within an acceptable range, as illustrated in FIG. 22. On the other hand, in a case where a significant difference is present between temporal variations of an attenuation rate b1 and/or a delay time Td, actual values that are temporally acquired multiple times concerning an attenuation rate b1 and/or a delay time Td are temporally and gradually detached from an adjustment value greatly, as illustrated in FIG. 23.

A technique to determine whether or not a significant difference is present between temporal variations of an attenuation rate b1 and/or a delay time Td is not limited, and typically, it is possible to determine presence or absence of such a significant difference, based on a magnitude of a slope of a regression line.

For example, in a case where an absolute value of a slope of a corresponding regression line that is calculated from values that are temporally acquired concerning an attenuation rate b1 and/or a delay time Td is greater than a significant difference determination reference value, it is possible to determine that a significant difference is present between temporal variations of such an attenuation rate b1 and/or a delay time Td. On the other hand, in a case where an absolute value of a slope of a corresponding regression line that is calculated from values that are temporally acquired concerning an attenuation rate b1 and/or a delay time Td is a significant difference determination reference value or less, it is possible to determine that a significant difference is absent between temporal variations of such an attenuation rate b1 and/or a delay time Td. Herein, a significant difference determination reference value is capable of being appropriately set by a manager, and it is possible to adopt any value that is greater than 0 as such a significant difference determination reference value.

In a case where a significant difference is absent between temporal variations of an attenuation rate b1 and a delay time Td (No at S36), the processing unit 10 executes a normal operation under control of the controller 93 (S38).

On the other hand, in a case where a significant difference is present between temporal variations of an attenuation rate b1 and a delay time Td (Yes at S36), the controller 93 issues an alarm (a temporal change indication alarm). Furthermore, in such a case, the controller 93 estimates a time (an expected acceptable range deviation time) when it is expected that an attenuation rate b1 and/or a delay time Td deviates from an acceptable range (S37).

Herein, a calculation method for an expected acceptable range deviation time is not limited. For example, as illustrated in FIG. 23, a time that is indicated by a point of intersection between an extended line of a regression line that is calculated from values that are temporally acquired concerning an attenuation rate b1 and/or a delay time Td and an upper limit threshold or a lower limit threshold that is determined with reference to an adjustment value may be provided as an expected acceptable range deviation time. Herein, an upper limit threshold and a lower limit threshold are not limited and are capable of being appropriately set by a manager.

It is possible for a manager to detect a temporal change of the processing liquid valve 21 and the fluid pressure adjustment unit 22, based on a temporal change indication alarm and/or an estimated expected acceptable range deviation time, so that it is possible to execute handling such as maintenance as needed.

As described above, a step of acquiring temporal information that indicates a temporal change of the processing liquid valve 21 based on a temporal change(s) of an attenuation rate b1 and/or a delay time Td is executed in the present example.

By a series of processes S31 to S38 as described above, it is possible to check presence or absence of state abnormality of the processing liquid valve 21 and the fluid pressure adjustment unit 22 and it is possible to expect a timing when such state abnormality is caused. A series of processes S31 to S38 as described above may be executed at any timing when such a check of state abnormality and expectation of a timing when state abnormality is caused is needed or may be executed regularly. For example, a series of processes S31 to S38 as described above may be executed at a time of activation of the processing unit 10 (that is capable of including a time of returning from an idling state), immediately after a maintenance process, immediately after a liquid process is continuously executed for a predetermined number or a predetermined lot number of substrates W, etc.

It should be noted that an embodiment(s) and a variation example(s) as disclosed in the present specification are not interpreted to be limitative and are merely illustrative in any aspect. An embodiment(s) and a variation example(s) as described above are capable of being omitted, substituted, and modified in a variety of modes without departing from the appended claim(s) and an essence thereof. For example, an embodiment(s) and a variation example(s) as described above may be combined entirely or partially, and further, an embodiment(s) other than that/those described above may be combined with an embodiment(s) and a variation example(s) as described above. Furthermore, an effect of the present disclosure as described in the present specification is merely illustrative and another effect may be exerted.

A technical category for implementing a technical idea(s) as described above is not limited. For example, a technical idea(s) as described above may be implemented by a computer program for causing a computer to execute one or more procedures (steps) that are included in a method for manufacturing, or a method for using, an apparatus as described above. Furthermore, a technical idea(s) as described above may be implemented by a computer-readable non-temporary (non-transitory) recording medium that records such a computer program therein.

1. A liquid processing method, comprising:
sending a processing liquid to a discharge nozzle through a processing liquid valve to discharge the processing liquid from the discharge nozzle toward a substrate where the processing liquid valve controls a flow of the processing liquid in a flow channel that is connected to the discharge nozzle, depending on a pressure of a working fluid that is supplied thereto, and a fluid pressure adjustment unit adjusts behavior of a variation of a pressure of the working fluid that is supplied to the processing liquid valve, depending on an adjustment parameter that is capable of being set variably;
limiting the processing liquid that is sent to the discharge nozzle through the processing liquid valve to stop discharge of the processing liquid from the discharge nozzle; and
acquiring correlation data between a working fluid parameter that indicates behavior of a variation of a pressure of the working fluid that is acquired by a fluid pressure measurement unit that measures a pressure of the working fluid that is supplied to the processing liquid valve, and the adjustment parameter.

2. The liquid processing method according to claim 1, further comprising
adjusting the adjustment parameter based on the working fluid parameter in light of a previous correlation data.

3. The liquid processing method according to claim 1, further comprising
determining a discharge state of the processing liquid from the discharge nozzle at a time when discharge of the processing liquid from the discharge nozzle is stopped, based on whether or not the working fluid parameter is included in an acceptable range thereof.

4. The liquid processing method according to claim 3, wherein
the acceptable range is determined based on correlation data that are acquired previously.

5. The liquid processing method according to claim 3, further comprising
issuing an alarm in a case where the working fluid parameter falls outside the acceptable range.

6. The liquid processing method according to claim 1, further comprising
acquiring temporal information that indicates a temporal change of the processing liquid valve, based on a temporal change of the working fluid parameter.

7. A liquid processing method, comprising:
sending a processing liquid to a discharge nozzle through a processing liquid valve to discharge the processing liquid from the discharge nozzle toward a processing surface of a substrate where the processing liquid valve controls a flow of the processing liquid in a flow channel that is connected to the discharge nozzle, depending on a pressure of a working fluid that is supplied thereto, and a fluid pressure adjustment unit adjusts behavior of a variation of a pressure of the working fluid that is supplied to the processing liquid valve, depending on an adjustment parameter that is capable of being set variably;
limiting the processing liquid that is sent to the discharge nozzle through the processing liquid valve, depending on a discharge stop signal, to stop discharge of the processing liquid from the discharge nozzle; and
irradiating the processing surface with light to detect an intensity of reflected light from the processing surface temporally and determining a discharge state of the processing liquid from the discharge nozzle at a time when discharge of the processing liquid from the discharge nozzle is stopped, based on a result of detection of an intensity of the reflected light.

8. The liquid processing method according to claim 7, wherein
an intensity of the reflected light in a case where the processing liquid is not present on the processing surface is higher than an intensity of the reflected light in a case where the processing liquid is present on the processing surface.

9. The liquid processing method according to claim 7, wherein
a discharge state of the processing liquid from the discharge nozzle at a time when discharge of the processing liquid from the discharge nozzle is stopped is determined based on a delay time that indicates a period of time after a timing when the discharge stop signal is emitted and before an intensity of the reflected light exceeds an intensity reference value thereof.

10. The liquid processing method according to claim 9, wherein
a discharge state of the processing liquid from the discharge nozzle at a time when discharge of the processing liquid from the discharge nozzle is stopped is determined based on whether or not the delay time is included in an acceptable range thereof.

11. The liquid processing method according to claim 9, wherein
a discharge state of the processing liquid from the discharge nozzle at a time when discharge of the processing liquid from the discharge nozzle is stopped is determined based on whether or not a working fluid parameter that indicates behavior of a variation of a pressure of the working fluid that is acquired by a fluid pressure measurement unit that measures a pressure of the working fluid that is supplied to the processing liquid valve, and the delay time are included in acceptable ranges thereof.

12. The liquid processing method according to claim 7, wherein
a discharge state of the processing liquid from the discharge nozzle at a time when discharge of the processing liquid from the discharge nozzle is stopped is determined based on a result of detection of an intensity of the reflected light at a point of time when a determination reference time passes after a timing when the discharge stop signal is emitted.

13. The liquid processing method according to claim 7, wherein
a discharge state of the processing liquid from the discharge nozzle at a time when discharge of the processing liquid from the discharge nozzle is stopped is determined based on a result of detection of an intensity of the reflected light after a timing when the discharge stop signal is emitted and before a determination reference time passes.

14. The liquid processing method according to claim 7, further comprising
issuing an alarm in a case where a number of times that an intensity of the reflected light exceeds a determination reference value thereof exceeds a number of times as a reference of determination, after a timing when the discharge stop signal is emitted and before a determination reference time passes.

15. The liquid processing method according to claim 9, further comprising
acquiring temporal information that indicates a temporal change of the processing liquid valve, based on a temporal change of the delay time.

16.-17. (canceled)

18. A liquid processing apparatus, comprising
a discharge nozzle that discharges a processing liquid toward a substrate;
a processing liquid valve that controls a flow of the processing liquid in a flow channel that is connected to the discharge nozzle, depending on a pressure of a working fluid that is supplied thereto;
a fluid pressure adjustment unit that adjusts behavior of a variation of a pressure of the working fluid that is supplied to the processing liquid valve, depending on an adjustment parameter that is capable of being set variably;
a fluid pressure measurement unit that measures a pressure of the working fluid that is supplied to the processing liquid valve; and
a controller that acquires correlation data between a working fluid parameter that indicates behavior of a variation of a pressure of the working fluid that is acquired by the fluid pressure measurement unit that measures a pressure of the working fluid that is supplied to the processing liquid valve, and the adjustment parameter.

19. (canceled)

20. The liquid processing apparatus according to claim 18, wherein
the controller sends the processing liquid to the discharge nozzle through the processing liquid valve.

21. The liquid processing apparatus according to claim 18, wherein
the controller limits the processing liquid that is sent to the discharge nozzle through the processing liquid valve to stop discharge of the processing liquid from the discharge nozzle.

22. The liquid processing apparatus according to claim 18, wherein
the controller irradiates a processing surface of the substrate with light to detect an intensity of reflected light from the processing surface temporally and determining a discharge state of the processing liquid from the discharge nozzle at a time when discharge of the processing liquid from the discharge nozzle is stopped, based on a result of detection of an intensity of the reflected light.
